(19) United States
(12) Patent Application Publication
(10) Pub. No.: US 2012/0273961 A1
(43) Pub. Date: Nov. 1, 2012

(54) SEMICONDUCTOR APPARATUS

(75) Inventors: Yong Kee KWON, Icheon-si (KR); Hyung Dong LEE, Icheon-si (KR); Young Suk MOON, Icheon-si (KR); Hyung Gyun YANG, Icheon-si (KR); Sung Wook KIM, Icheon-si (KR)

(73) Assignee: HYNIX SEMICONDUCTOR INC., Icheon-si (KR)

(21) Appl. No.: 13/219,645

(22) Filed: Aug. 27, 2011

(30) Foreign Application Priority Data
Apr. 28, 2011 (KR) 10-2011-0040289

(51) Int. Cl. H01L 23/48

(52) U.S. Cl. 257/774; 257/E23.011

(57) ABSTRACT

A semiconductor apparatus includes a plurality of semiconductor chips which are stacked; and an auxiliary semiconductor chip configured to recover and transmit signals of the plurality of semiconductor chips through a plurality of through vias which extend vertically, at a predetermined time interval.

### CROSS-REFERENCES TO RELATED APPLICATION

The present application claims priority under 35 U.S.C. §119(a) to Korean application number 10-2011-0040289, filed on Apr. 28, 2011, in the Korean Intellectual Property Office, which is incorporated herein by reference in its entirety as set forth in full.

### BACKGROUND

1. Technical Field

The present invention relates generally to a semiconductor integrated circuit, and more particularly, to a semiconductor chip stacking technology.

2. Related Art

The packaging technology for a semiconductor integrated circuit has continuously been developed to meet the demand toward miniaturization and high capacity. Recently, various packaging technologies for miniaturization and high capacity such as stack package technology are being developed.

The term “stack package”, which is referred to in the semiconductor industry, means a semiconductor package in which at least two chips or packages are stacked in a vertical configuration. Through the stack package technology, it is possible to realize a product having a high memory capacity, which is greater than that obtainable through semiconductor integration processes, and high space efficiency.

Stack package manufacturing methods can be divided into a method in which individual semiconductor chips are stacked and the stacked semiconductor chips are packaged, and a method in which individually packaged semiconductor chips are stacked. In a stack package, a plurality of stacked semiconductor chips or packages are electrically connected with one another through metal wires, bumps or through-silicon vias (TSVs) which are formed between the stacked semiconductor chips or packages.

However, in a known stack package technology, since a redistribution process is required when stacking different kinds of semiconductor chips, a processing time is lengthened and a manufacturing yield decreases. Also, as the resistance of semiconductor chips increases due to the presence of redistribution lines, the electrical characteristics of the semiconductor chips may be degraded.

### SUMMARY

A semiconductor apparatus capable of improving the characteristics of a package is described herein.

In an embodiment of the present invention, a semiconductor apparatus includes: a plurality of semiconductor chips mounted in such a way as to be stacked upon one another; and an auxiliary semiconductor chip configured to recover and transmit lost signals of the plurality of semiconductor chips through through vias which extend vertically, every time a predetermined time interval is lapsed.

In an embodiment of the present invention, a semiconductor apparatus includes: a plurality of semiconductor chips mounted in such a way as to be stacked upon one another; and an auxiliary semiconductor chip connected to the plurality of semiconductor chips through through vias which extend vertically, and configured to decouple noise between the plurality of semiconductor chips.

In an embodiment of the present invention, a semiconductor apparatus includes: a plurality of semiconductor groups each including a plurality of semiconductor chips; and an auxiliary semiconductor group including a plurality of auxiliary semiconductor chips which are arranged between the plurality of semiconductor groups and are connected with the semiconductor groups by through vias which extend vertically, and configured to recover and transmit lost signals of the plurality of semiconductor chips every time a predetermined time interval is lapsed.

### BRIEF DESCRIPTION OF THE DRAWINGS

Features, aspects, and embodiments are described in conjunction with the attached drawings, in which:

FIGS. 1a and 1b are views illustrating a semiconductor apparatus in accordance with an embodiment of the present invention;

FIGS. 2a and 2b are views illustrating a semiconductor apparatus in accordance with an embodiment of the present invention; and

FIGS. 3a and 3b are views illustrating a semiconductor apparatus in accordance with an embodiment of the present invention.

### DETAILED DESCRIPTION

Hereinafter, a semiconductor apparatus according to the present invention will be described below with reference to the accompanying drawings through exemplary embodiments.

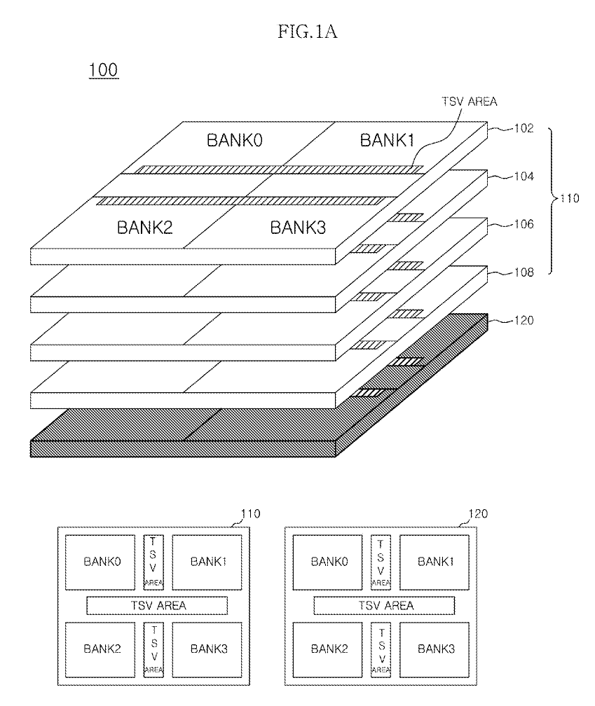

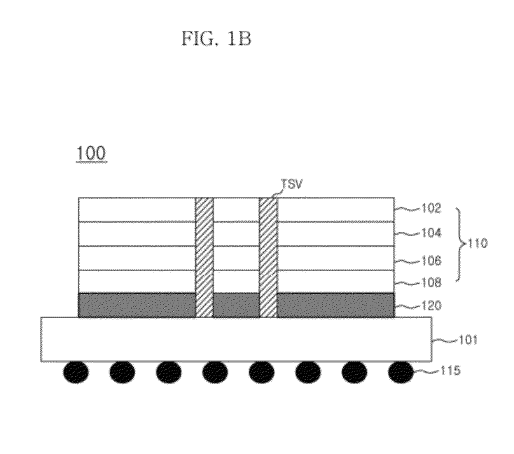

FIGS. 1a and 1b are views illustrating a semiconductor apparatus in accordance with an embodiment of the present invention.

Referring to FIGS. 1a and 1b, a stacked memory module 100 in accordance with an embodiment of the present invention includes a plurality of memory chips 110 and an auxiliary memory chip 120.

The plurality of memory chips 110 include first to fourth memory chips 102, 104, 106 and 108 which are electrically connected in series.

The plurality of memory chips 110 according to an embodiment of the present invention may be constituted by a combination of at least any one of, for example, a NAND flash memory, a NOR flash memory, an EEPROM, an MRAM, a PCRAM, an ReRAM, an FeRAM, an SRAM, a PSRAM and a DRAM.

As shown in FIG. 1a, each of the plurality of memory chips 110 may be configured to include 4 banks and through-silicon via regions.

Each bank includes a plurality of memory cells (not shown) which are arranged in rows and columns. Each memory cell can store data.

The through-silicon via regions, in which through-silicon vias (TSVs) are to be formed, may be positioned between the respective banks.

The TSVs may serve as, according to an example, data bus lines which transmit address signals, control signals and data signals to the plurality of memory chips 110.

As shown in FIG. 1b, the auxiliary memory chip 120 is mounted on a semiconductor substrate 101, and may be arranged under the fourth memory chip 108 which is positioned lowermost among the plurality of memory chips 110.

The auxiliary memory chip 120 may include 4 banks and through-silicon via regions in the same manner as the plurality of memory chips 110. The through-silicon via regions serve as regions in which TSVs are to be formed. In the same manner as the through-silicon via regions of the plurality of memory chips 110, the through-silicon via regions of the auxiliary memory chip 120 may be formed between the respective banks.

According to this fact, as can be seen from FIG. 1b, the TSVs of the auxiliary memory chip 120 and the TSVs of the plurality of memory chips 110 may be formed to be connected with one another in the vertical direction.

The auxiliary memory chip 120 may include a silicon chip, a printed circuit board, a circuit tape, a circuit film or an equivalent. In an embodiment of the present invention, the kind of the auxiliary memory chip 120 is not specifically limited.

The TSVs of the auxiliary memory chip 120 may electrically connect the plurality of stacked semiconductor chips 110 with the semiconductor substrate 101 by passive elements such as inductors, capacitors or resistors, or by logic elements such as processors, which are included in the auxiliary memory chip 120.

That is to say, the auxiliary memory chip 120 is arranged between the semiconductor substrate 101 and the plurality of memory chips 110, and serves as an interposer which electrically connects the plurality of memory chips 110 with one another or the plurality of memory chips 110 with an outside.

The top and bottom structures of the auxiliary memory chip 120 may vary according to factors such as the size of the memory chip 112, 104, 106 or 108, the number of the plurality of memory chips 110 to be mounted, and the number of input/output pads.

In this way, in the semiconductor apparatus 100 according to an embodiment of the present invention, when stacking the plurality of memory chips 110 of various kinds, the auxiliary memory chip 120 may be additionally arranged under the lowermost one of the various kinds of memory chips 110.

The auxiliary memory chip 120 according to an embodiment of the present invention can electrically connect the various kinds of memory chips 110 with one another regardless of input/output of the various kinds of memory chips 110, and thus the characteristics of a package may be secured.

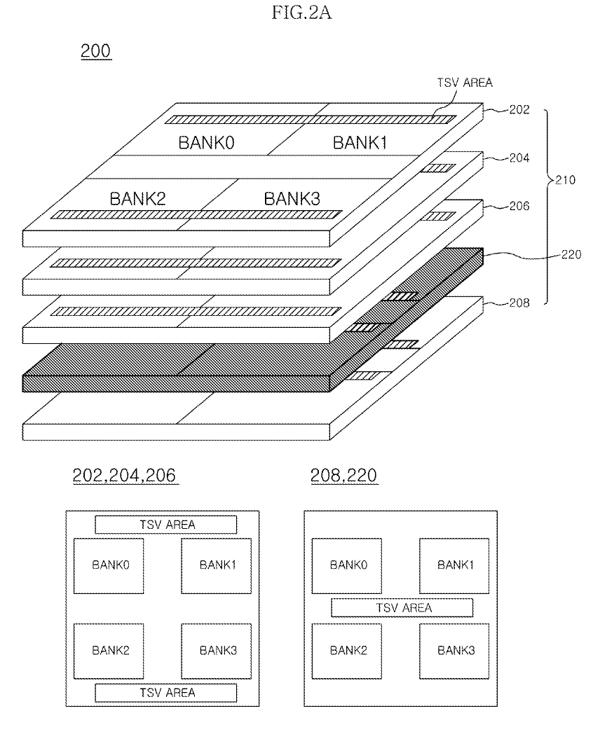

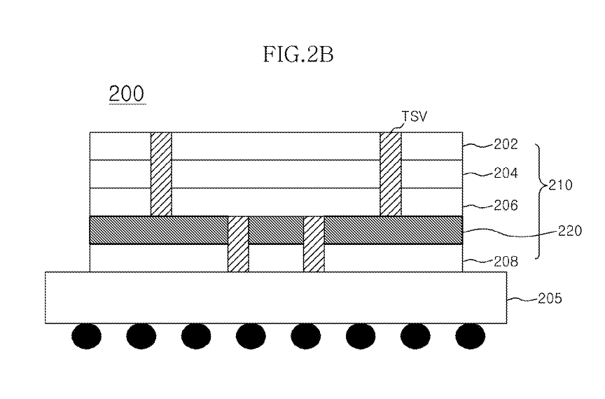

FIGS. 2a and 2b are views illustrating a semiconductor apparatus in accordance with an embodiment of the present invention.

Referring to FIGS. 2a and 2b, a stacked memory module 200 in accordance with an embodiment of the present invention includes a plurality of memory chips 210 and an auxiliary memory chip 220.

The plurality of memory chips 210 may be constituted by a combination of at least any one of, for example, a NAND flash memory, a NOR flash memory, an EEPROM, an MRAM, a PCRAM, an ReRAM, an FeRAM, an SRAM, a PSRAM and a DRAM.

As shown in FIG. 2b, the plurality of memory chips 210 are stacked and are mounted to a semiconductor substrate 205.

As shown in FIG. 2a, each of the plurality of memory chips 210 may be configured to include 4 banks and through-silicon via regions.

Each bank includes a plurality of memory cells (not shown) which are arranged in rows and columns. Each memory cell can store data.

The through-silicon via regions serve as regions in which through-silicon vias (TSVs) are to be formed. The TSVs may serve as, according to an example, data bus lines which transmit address signals, control signals and data signals to the plurality of memory chips 210.

The through-silicon via regions of the three memory chips 202, 204 and 206 among the plurality of memory chips 210, which are mounted over the auxiliary memory chip 220, may be formed outside the respective banks or the edge of the respective banks, and the through-silicon via regions of the one memory chip 208 among the plurality of memory chips 210, which is mounted under the auxiliary memory chip 220, may be formed between the respective banks.

The auxiliary memory chip 220 is arranged between the plurality of memory chips 210. In detail, the three separate memory chips 202, 204 and 206 are mounted over the auxiliary memory chip 220, and the one memory chip 208 is mounted under the auxiliary memory chip 220.

The auxiliary memory chip 220 may include 4 banks and through-silicon via regions in the same manner as the plurality of memory chips 210. The through-silicon via regions serve as regions in which TSVs are to be formed, and may be formed between the respective banks.

The auxiliary memory chip 220 may include a silicon chip, a printed circuit board, a circuit tape, a circuit film or an equivalent. In an embodiment of the present invention, the kind of the auxiliary memory chip 220 is not specifically limited.

The TSVs of the auxiliary memory chip 220 may electrically connect the plurality of stacked semiconductor chips 210 with the semiconductor substrate 205 by passive elements such as inductors, capacitors or resistors, or by logic elements such as processors, which are included in the auxiliary memory chip 220.

The auxiliary memory chip 220 is arranged between the plurality of memory chips 210, and serves as an interposer which electrically connects the plurality of memory chips 210 with one another.

The auxiliary memory chip 220 according to an embodiment of the present invention may serve as a repeater which compensates for a voltage decreasing with the lapse of time, so as to prevent a loading time from being delayed by the TSVs of the plurality of memory chips 210 formed at different positions.

The auxiliary memory chip 220 according to an embodiment of the present invention may also serve as a decoupling capacitor by including resistors and capacitors.

As the auxiliary memory chip 220 serves as a decoupling capacitor, decoupling of upper and lower chips can be accomplished. Due to this fact, the auxiliary memory chip 220 functions to recover and transmit the signals of the plurality of memory chips 210 and decouple noise.

Besides, the auxiliary memory chip 220 according to an embodiment of the present invention may include, in addition to a circuit for a core operation of the semiconductor apparatus 200, a circuit such as for a built-in self test (BIST) operation, which is not related to a main operation of the semiconductor apparatus 200.

In this way, in the semiconductor apparatus 200 according to an embodiment of the present invention, due to the fact that the auxiliary memory chip 220 is arranged between the plurality of memory chips 210, it is possible to prevent a loading time from being delayed by the TSVs of the plurality of memory chips 210 formed at different positions.

Moreover, the auxiliary memory chip 220 according to an embodiment of the present invention may function to recover and transmit the signals of the plurality of memory chips 210 at a predetermined time interval and decouple noise.

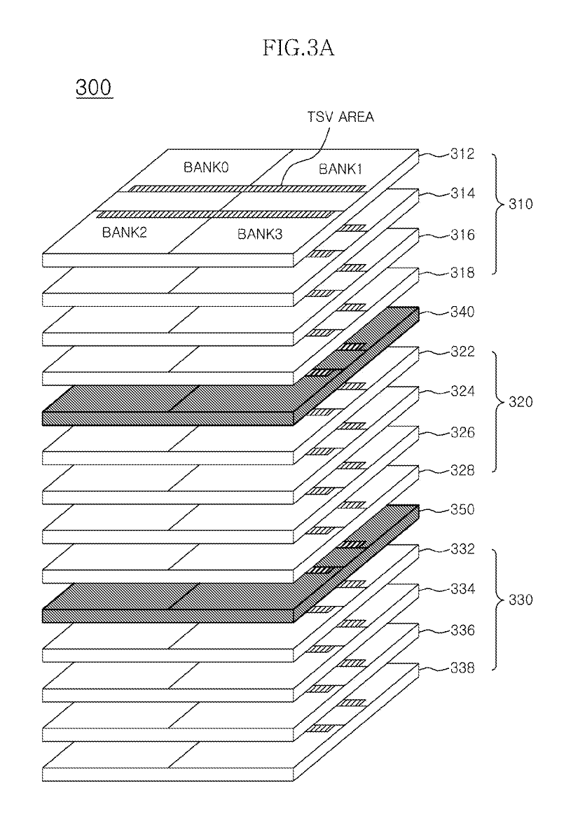

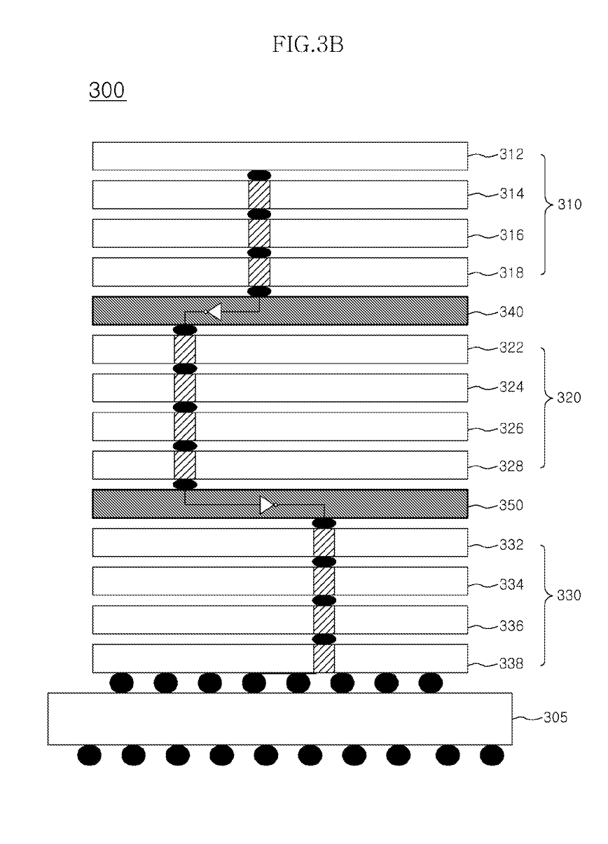

FIGS. 3a and 3b are views illustrating a semiconductor apparatus in accordance with an embodiment of the present invention.

Referring to FIGS. 3a and 3b, a stacked memory module 300 in accordance with an embodiment of the present invention includes a plurality of memory groups 310, 320 and 330 and a plurality of auxiliary memory groups 340 and 350.

Each of the plurality of memory groups 310, 320 and 330 includes 4 memory chips which are stacked.

In detail, the first memory group 310 among the plurality of memory groups 310, 320 and 330 is arranged uppermost among the plurality of memory groups 310, 320 and 330, and includes first to fourth memory chips 312, 314, 316 and 318 which are stacked.

The second memory group 320 among the plurality of memory groups 310, 320 and 330 is arranged between the first memory group 310 and the third memory group 330, and includes fifth to eighth memory chips 322, 324, 326 and 328 which are stacked.

The third memory group 330 among the plurality of memory groups 310, 320 and 330 is arranged lowermost among the plurality of memory groups 310, 320 and 330 and contacts a semiconductor substrate 305 (see FIG. 3b), and includes ninth to twelfth memory chips 332, 334, 336 and 338 which are stacked.

The plurality of memory chips, that is, the first to twelfth memory chips 312, 314, 316, 318, 322, 324, 326, 328, 332, 334, 336 and 338 may be constituted by a combination of at least any one of, for example, a NAND flash memory, a NOR flash memory, an EEPROM, an MRAM, a PCRAM, an ReRAM, an FeRAM, an SRAM, a PSRAM and a DRAM.

Each of the first to twelfth memory chips 312, 314, 316, 318, 322, 324, 326, 328, 332, 334, 336 and 338 may be configured to include a plurality of banks and through-silicon via regions. Since the plurality of memory chips according to an embodiment are configured in the same manner as the plurality of memory chips of the embodiments, detailed descriptions thereof will be omitted herein.

The respective auxiliary memory groups 340 and 350 are arranged between the plurality of memory groups 310, 320 and 330 and may reduce loading by TSVs.

In detail, one auxiliary memory group 340 of the auxiliary memory groups 340 and 350 is arranged between the first memory group 310 and the second memory group 320, and the other auxiliary memory group 350 of the auxiliary memory groups 340 and 350 is disposed between the second memory group 320 and the third memory group 330.

Each of the auxiliary memory groups 340 and 350 may include 4 banks and through-silicon via regions in the same manner as the plurality of memory groups 310, 320 and 330. The through-silicon via regions serve as regions in which TSVs are to be formed, and may be formed, for example, between the banks, outside the banks and in the banks.

Each of the auxiliary memory groups 340 and 350 may include a printed circuit board, a circuit tape, a circuit film or an equivalent. In an embodiment of the present invention, the kind of the auxiliary memory groups 340 and 350 is not specifically limited.

The TSVs of the auxiliary memory groups 340 and 350 may electrically connect the stacked memory groups 310, 320 and 330 with the semiconductor substrate 305 by passive elements such as inductors, capacitors or resistors, or by logic elements such as processors, which are included in the auxiliary memory groups 340 and 350.

The auxiliary memory groups 340 and 350 may be arranged between the semiconductor substrate 305 and the plurality of memory groups 310, 320 and 330, and may serve as interposers which electrically connect the plurality of memory groups 310, 320 and 33 with one another or the plurality of memory groups 310, 320 and 330 with an outside.

In addition, the auxiliary memory groups 340 and 350 according to an embodiment of the present invention may serve as repeaters which compensate for voltages decreasing with the lapse of time, so as to prevent loading times from being delayed by the TSVs formed at different positions.

The auxiliary memory groups 340 and 350 according to an embodiment of the present invention may also serve as decoupling capacitors by including resistors and capacitors.

As the auxiliary memory groups 340 and 350 serve as decoupling capacitors, decoupling of upper and lower memory groups can be accomplished. Due to this fact, the auxiliary memory groups 340 and 350 function to recover and transmit the signals of the plurality of memory groups 310, 320 and 330 and decouple noise.

Besides, each of the auxiliary memory groups 340 and 350 according to an embodiment of the present invention may include, in addition to a circuit for a core operation of the semiconductor apparatus 300, a circuit such as for a built-in self test (BIST) operation, which is not related to a main operation of the semiconductor apparatus 300.

In this way, in the semiconductor apparatus 300 according to an embodiment of the present invention, due to the fact that the auxiliary memory groups 340 and 350 are arranged between the plurality of memory groups 310, 320 and 330, it is possible to prevent a loading time from being delayed by the TSVs of the plurality of memory groups 310, 320 and 330 formed at different positions.

Moreover, the auxiliary memory groups 340 and 350 according to an embodiment of the present invention may function to recover and transmit the signals of the plurality of memory groups 310, 320 and 330 at a predetermined time interval and decouple noise.

As is apparent from the above descriptions, in the semiconductor apparatus according to the embodiments of the present invention, when stacking a plurality of memory chips of various kinds, an auxiliary memory chip is arranged under the lowermost one of the various kinds of memory chips. Therefore, since the various kinds of memory chips can be electrically connected, the characteristics of a package may be secured.

Further, in the semiconductor apparatus according to the embodiments of the present invention, as an auxiliary memory chip is arranged between a plurality of memory chips or a plurality of memory groups, a delay of a loading time may decrease by TSVs of the plurality of memory chips or the plurality of memory groups formed at different positions.

Moreover, in the semiconductor apparatus according to the embodiments of the present invention, the auxiliary memory chip may function to recover and transmit the signals of the plurality of memory chips or the plurality of memory groups at a predetermined time interval and decouple noise.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

What is claimed is:

1. A semiconductor apparatus comprising:
a plurality of semiconductor chips which are stacked; and
an auxiliary semiconductor chip configured to recover and transmit signals of the plurality of semiconductor chips through a plurality of through vias which extend vertically, at a predetermined time interval.

2. The semiconductor apparatus according to claim 1, wherein the through vias are through-silicon vias.

3. The semiconductor apparatus according to claim 1, wherein the auxiliary semiconductor chip serves as an interposer which electrically connects the plurality of semiconductor chips.

4. The semiconductor apparatus according to claim 1, wherein each of the plurality of semiconductor chips is formed with the through vias which extend vertically.

5. The semiconductor apparatus according to claim 4, wherein the through vias of the plurality of semiconductor chips are formed at positions corresponding to the through vias of the auxiliary semiconductor chip.

6. The semiconductor apparatus according to claim 5, wherein the auxiliary semiconductor chip is arranged on a back side of a semiconductor chip which is positioned lowermost among the plurality of semiconductor chips.

7. The semiconductor apparatus according to claim 4, wherein the through vias of the plurality of semiconductor chips are formed at different positions from the through vias of the auxiliary semiconductor chip.

8. The semiconductor apparatus according to claim 7, wherein the auxiliary semiconductor chip is arranged between the plurality of semiconductor chips.

9. A semiconductor apparatus comprising:
a plurality of semiconductor chips which are stacked; and
an auxiliary semiconductor chip connected to the plurality of semiconductor chips through a plurality of through vias which extend vertically, and configured to decouple noise between the plurality of semiconductor chips.

10. The semiconductor apparatus according to claim 9, wherein the through vias are through-silicon vias.

11. The semiconductor apparatus according to claim 9, wherein the auxiliary semiconductor chip serves as an interposer which electrically connects the plurality of semiconductor chips.

12. The semiconductor apparatus according to claim 9, wherein each of the plurality of semiconductor chips is formed with the through vias which extend vertically.

13. The semiconductor apparatus according to claim 12, wherein the through vias of the plurality of semiconductor chips are formed at different positions from the through vias of the auxiliary semiconductor chip.

14. The semiconductor apparatus according to claim 13, wherein the auxiliary semiconductor chip is arranged between the plurality of semiconductor chips.

15. The semiconductor apparatus according to claim 14, wherein the auxiliary semiconductor chip recovers and transmits signals of the plurality of semiconductor chips at a predetermined time interval.

16. A semiconductor apparatus comprising:
a plurality of semiconductor groups each including a plurality of semiconductor chips; and
an auxiliary semiconductor group including a plurality of auxiliary semiconductor chips which are arranged between the plurality of semiconductor groups and are connected with the semiconductor groups by through vias which extend vertically, and configured to recover and transmit signals of the plurality of semiconductor chips at a predetermined time interval.

17. The semiconductor apparatus according to claim 16, wherein the through vias are through-silicon vias.

18. The semiconductor apparatus according to claim 16, wherein the auxiliary semiconductor group serves as an interposer which electrically connects the plurality of semiconductor groups.

19. The semiconductor apparatus according to claim 16, wherein the auxiliary semiconductor groups decouples noise between the plurality of semiconductor groups.
